(19) United States
(12) Patent Application Publication
(10) Pub. No.: US 2011/0278047 A1
(43) Pub. Date: Nov. 17, 2011

(54) FLEXIBLE PRINTED CIRCUIT BOARD

(75) Inventors: Yasuyuki Yamauchi, Osaka (JP); Kazuhiro Yamaji, Osaka (JP); Tsutomu Abe, Kanagawa (JP); Shinya Iizaka, Kanagawa (JP)

(73) Assignees: SUMITOMO ELECTRIC DEVICE INNOVATIONS, INC., Yokohama-shi (JP); SUMITOMO ELECTRIC INDUSTRIES, LTD., Osaka (JP)

(21) Appl. No.: 13/105,993

(22) Filed: May 12, 2011

(30) Foreign Application Priority Data
May 13, 2010 (JP) 2010-111421

(51) Int. Cl. H05K 1/00

(52) U.S. Cl. 174/254

(57) ABSTRACT

A flexible printed circuit board includes: a substrate having a first edge and a second edge; a first wiring pattern disposed on the substrate and having a lead connection portion at a side of the first edge of the substrate; a second wiring pattern disposed on the substrate and having a lead connection portion at a side of the first edge of the substrate; a first solder pattern disposed on the lead connection portion of the first wiring pattern; and a second solder pattern disposed on the lead connection portion of the second wiring pattern and having a length longer than the first solder pattern.

### CROSS-REFERENCE TO RELATED APPLICATION

This application is based upon and claims the benefit of priority of the prior Japanese Patent Application No. 2010-111421, filed on May 13, 2010, the entire contents of which are incorporated herein by reference.

### BACKGROUND

(i) Technical Field

The present invention relates to a flexible printed circuit board.

(ii) Related Art

A flexible printed circuit (FPC) board is used for a coupling of an electronic circuit. It is known that a wiring of the flexible printed circuit board may be broken when the flexible printed circuit board is bended. Japanese Examined Utility Model Application Publication No. 07-22668 discloses that a reinforced board for strengthening the flexible printed circuit board is used in order to restrain the breaking of a wiring, and discloses that an insulating cover film is provided on an upper face and a lower face of a flexible printed circuit board in order to protect the flexible printed circuit board and a shape of the insulating cover film of the upper face is different from that of the lower face.

### SUMMARY

It may be difficult to use the reinforced board because the flexible printed circuit board gets inflexible when the reinforced board is used. It may be difficult to restrain the breaking of a wiring with the different shapes of the insulating cover films of the upper face and the lower face.

It is an object of the present invention to restrain a breaking of a wiring of a flexible printed circuit board.

According to an aspect of the present invention, there is provided a flexible printed circuit board including: a substrate having a first edge and a second edge; a first wiring pattern disposed on the substrate and having a lead connection portion at a side of the first edge of the substrate; a second wiring pattern disposed on the substrate and having a lead connection portion at a side of the first edge of the substrate; a first solder pattern disposed on the lead connection portion of the first wiring pattern; and a second solder pattern disposed on the lead connection portion of the second wiring pattern and having a length longer than the first solder pattern. In accordance with the present invention, the breaking of a wiring in the flexible printed circuit board is restrained.

The flexible printed circuit board may further include a third wiring pattern disposed on the substrate and having a lead connection portion at a side of the first edge of the substrate; and a third solder pattern that is disposed on the lead connection portion of the third wiring pattern and is longer than a length of the first solder pattern and shorter than a length of the second solder pattern. With the structure, the breaking of a wiring in the flexible printed circuit board is restrained more.

The flexible printed circuit board may further include a covering sheet disposed on the first and second wiring patterns, the first and second solder pattern being exposed from the covering sheet. With the structure, the breaking of a wiring in the flexible printed circuit board is restrained more.

The first and second solder patterns may be extended to an edge of the covering sheet.

The third wiring pattern may be arranged between the first and second wiring patterns. With the structure, the breaking of a wiring in the flexible printed circuit board is restrained more.

The second solder pattern may have a width larger than a width of the first solder pattern.

According to another aspect of the present invention, there is provided an optical sub-assembly including: a package for holding an optical device; leads electrically connected to the optical device; and a flexible printed circuit board connected to the leads, the flexible printed circuit board comprising: a substrate having a first edge and a second edge; a first wiring pattern disposed on the substrate and having a lead connection portion at a side of the first edge of the substrate; a second wiring pattern disposed on the substrate and having a lead connection portion at a side of the first edge of the substrate; a first solder pattern disposed on the lead connection portion of the first wiring pattern; and a second solder pattern disposed on the lead connection portion of the second wiring pattern and having a length longer than the first solder pattern. In accordance with the present invention, the breaking of a wiring in the flexible printed circuit board is restrained.

A length in which the lead and the second solder pattern are contacted is longer than a length in which the lead and the first solder pattern may be contacted. The flexible printed circuit board may have a third wiring pattern that is disposed on the substrate and has a lead connection portion at a side of the first edge of the substrate, and a third solder pattern that is disposed on the lead connection portion of the third wiring pattern and is longer than a length of the first solder pattern and shorter than a length of the second solder pattern. A length in which the lead and the second solder pattern are contacted is longer than a length in which the lead and the third solder pattern may be contacted. A length in which the lead and the third solder pattern are contacted is longer than a length in which the lead and the first solder pattern may be contacted. A length in which the lead and the second solder pattern are contacted is the same as a length in which the lead and the first solder pattern may be contacted.

### BRIEF DESCRIPTION OF THE DRAWINGS

FIG. 1 illustrates a top view of a flexible substrate and a wiring pattern;

FIG. 2A illustrates a top view of a flexible printed circuit board in accordance with a first embodiment;

FIG. 2B illustrates side view of the flexible printed circuit board;

FIG. 3A illustrates a top view of a flexible printed circuit board in accordance with a comparative embodiment;

FIG. 3B illustrates side view of the flexible printed circuit board;

FIG. 4A illustrates a top view of a flexible printed circuit board in accordance with a second embodiment;

FIG. 4B illustrates side view of the flexible printed circuit board;

FIG. 5A illustrates a top view of another example of the flexible printed circuit board in accordance with the comparative embodiment;

FIG. 5B illustrates side view of the flexible printed circuit board;

FIG. 6A illustrates a top view of a flexible printed circuit board in accordance with a third embodiment;

FIG. 6B illustrates side view of the flexible printed circuit board;

FIG. 7A illustrates a top view of a flexible printed circuit board in accordance with a fourth embodiment;

FIG. 7B illustrates side view of the flexible printed circuit board;

FIG. 8A illustrates a top view of a flexible printed circuit board in accordance with a fifth embodiment;

FIG. 8B illustrates side view of the flexible printed circuit board;

FIG. 9A illustrates a top view of a flexible printed circuit board in accordance with a sixth embodiment;

FIG. 9B illustrates side view of the flexible printed circuit board;

FIG. 10 illustrates a schematic view of a seventh embodiment;

FIG. 11A illustrates an upper face of a flexible printed circuit board in accordance with the seventh embodiment; and

FIG. 11B illustrates a lower face of the flexible printed circuit board.

### DETAILED DESCRIPTION

A description will be given of a best mode for carrying the present invention.

### First Embodiment

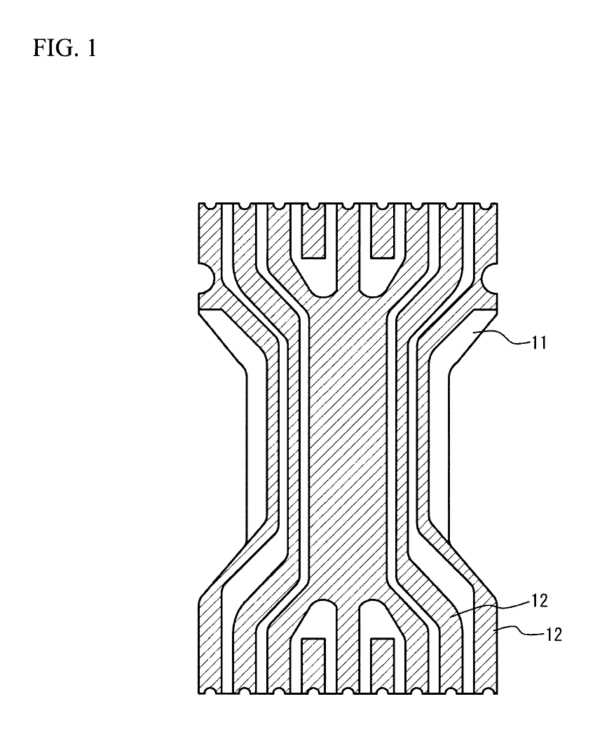

FIG. 1 illustrates a top view of a flexible substrate and a wiring pattern thereof. A wiring pattern 12 is formed on an upper face of a flexible substrate 11. The flexible substrate 11 is made of an insulating material such as a flexible resin. For example, the flexible substrate 11 has a thickness of approximately 50 μm. The wiring pattern 12 is, for example, made of a low resistivity metal such as Cu, Au or the like. The wiring pattern 12 continuously extends from a first edge to a second edge of the flexible substrate 11. For example, the wiring pattern 12 has a thickness of approximately 40 μm. Thus, an electrical signal may be coupled from the first edge to the second edge of the flexible substrate 11. The wiring pattern 12 may be provided only on the upper face. The wiring pattern 12 may be provided on both the upper face and the lower face.

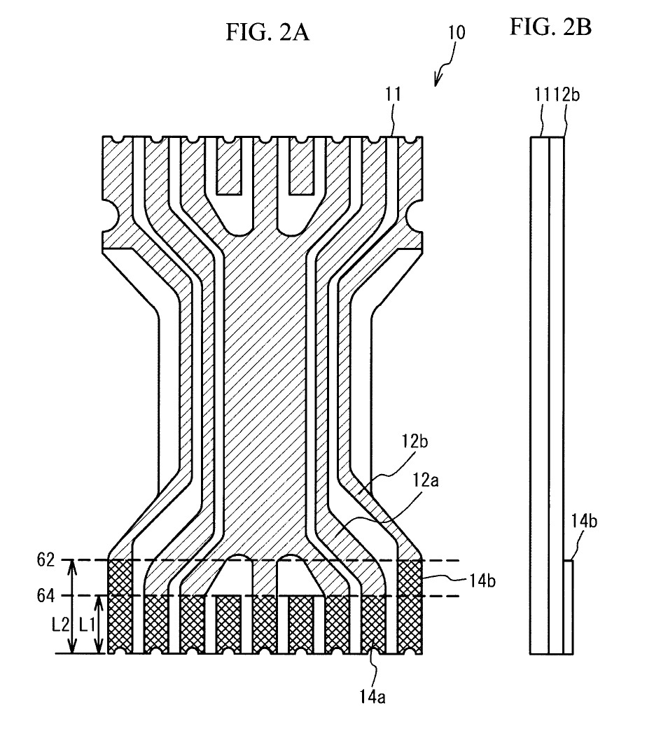

FIG. 2A illustrates a top view of a flexible printed circuit board in accordance with a first embodiment. FIG. 2B illustrates a side view of the flexible printed circuit board. As illustrated in FIG. 2A and FIG. 2B, a flexible printed circuit board 10 has a first wiring pattern 12a and a second wiring pattern 12b on the upper face of the flexible substrate 11. That is, the first wiring pattern 12a and the second wiring pattern 12b are disposed on the flexible substrate 11. The flexible substrate 11 has the first edge and the second edge as both edges in an extending direction of the first wiring pattern 12a. A first solder pattern 14a is disposed on a lead connection portion of the first wiring pattern 12a on the side of the first edge of the flexible substrate 11. The lead connection portion is a region to which a lead is to be connected. A second solder pattern 14b is disposed on a lead connection portion of the second wiring pattern 12b on the side of the first edge of the flexible substrate 11. The second solder pattern 14b is longer than the first solder pattern 14a in the extending direction of the first wiring pattern 12a and the second wiring pattern 12b. The solder is, for example, made of a solder such as AgSnCu or AgSnBiCu. It is preferable that the solder is harder. For example, it is preferable that the solder includes Bi (bismuth). The first solder pattern 14a and the second solder pattern 14b may be disposed on the first wiring pattern 12 and the second wiring pattern 12b with use of a printing method such as a screen printing method or a stamp printing method. It is preferable that the first solder pattern 14a and the second solder pattern 14b are made of the same material, in view of manufacturing. The first solder pattern 14a has a length L1 of 1.0 mm. The second solder pattern 14b has a length L2 of 2.0 mm. The first solder pattern 14a and the second solder pattern 14b have a thickness of approximately 30 μm.

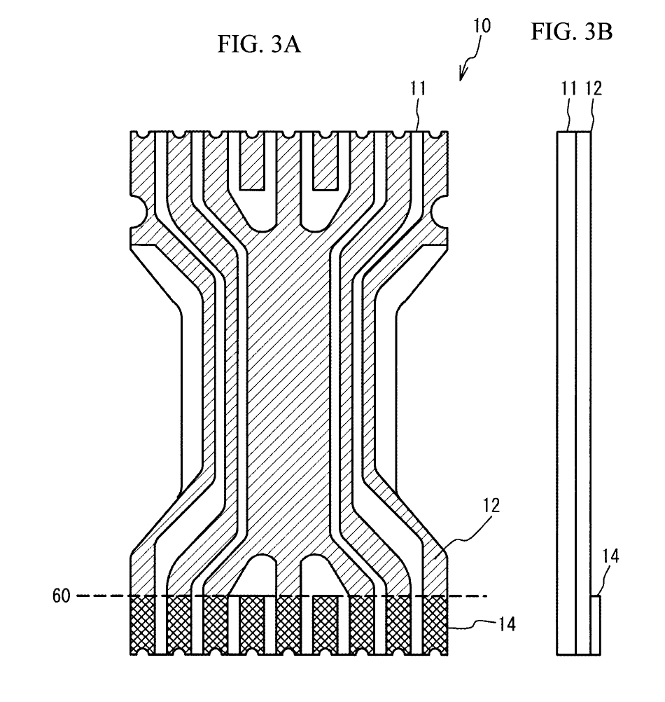

The above-mentioned solder patterns may be disposed on the first wiring pattern 12a and the second wiring pattern 12b on an opposite side of the first solder pattern 14a (on the side of the second edge of the flexible substrate 11). A description will be given of an effect of the first embodiment by comparison with a comparative embodiment. FIG. 3A illustrates a top view of a flexible printed circuit board in accordance with the comparative embodiment. FIG. 3B illustrates a side view of the flexible printed circuit board. As illustrated in FIG. 3A and FIG. 3B, in the comparative embodiment, each solder pattern on the wiring pattern has the same length. The other structure is the same as that of FIG. 2A and FIG. 2B.

In the comparative embodiment, each solder pattern 14 has the same length, and each end portion of the solder pattern 14 is on a straight line. This may cause stress concentration on a dotted line 60 of FIG. 3A, when the flexible substrate 11 is bended. This may cause a breaking of the wiring pattern having a small width. On the other hand, in the first embodiment, the length of the first solder pattern 14a is different from that of the second solder pattern 14b. Therefore, the end portion of the solder patterns is on a plurality of straight lines. This allows stress distribution as illustrated with a dotted line 62 and a dotted line 64 of FIG. 2A, when the flexible substrate 11 is bended. Therefore, each stress is reduced, and the breaking of the first wiring pattern 12a and the second wiring pattern 12b is restrained.

In accordance with the first embodiment, the second solder pattern 14b has a longer length than the first solder pattern 14a. This allows the stress distribution when the flexible substrate 11 is bended. Therefore, the breaking of the first wiring pattern 12a and the second wiring pattern 12b is restrained.

The second wiring pattern 12b having the second solder pattern 14b is located on both sides of the flexible substrate 11 (both sides in an array direction of the first wiring pattern 12a and the second wiring pattern 12b). The first wiring pattern 12a having the first solder pattern 14a is located at inner side compared to the second wiring pattern 14b. The breaking of the first wiring pattern 12a and the second wiring pattern 12b may be restrained more because the longer solder pattern is located outermost. It is preferable that a plurality of the first solder patterns 14a and a plurality of the second solder patterns 14b are disposed. This is because the breaking of the first wiring pattern 12a and the second wiring pattern 12b may be restrained more.

### Second Embodiment

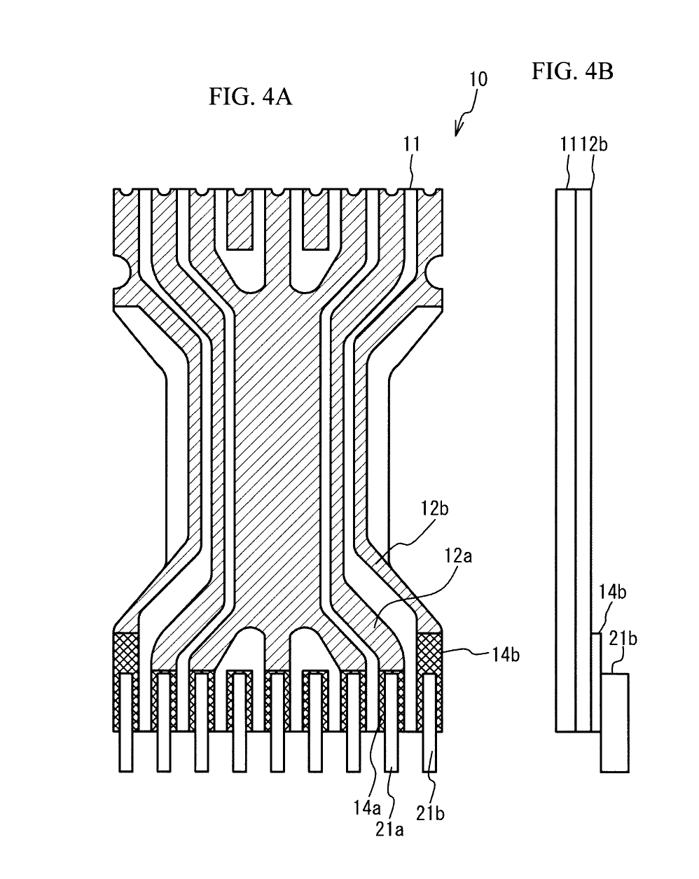

A second embodiment is an example where a lead is provided. FIG. 4A illustrates a top view of a flexible printed circuit board in accordance with the second embodiment. FIG. 4B illustrates a side view of the flexible printed circuit board. As illustrated in FIG. 4A and FIG. 4B, a first lead 21a is connected to the first wiring pattern 12a with use of the first solder pattern 14a, and a second lead 21b is connected to the second wiring pattern 12b with use of the second solder pattern 14b. For example, the first lead 21a and the second lead 21b have a width of 0.2 mm and a thickness of 0.1 mm. The other structure is the same as that of FIG. 2A and FIG. 2B. The length of the second lead 21b on the flexible substrate 11 is substantially the same as that of the first lead 21a on the flexible substrate 11. The first lead 21a and the second lead 21b may be a lead of a circuit substrate coupled to the flexible substrate 11. The first lead 21a and the second lead 21b are made of a metal such as kovar, Cu or the like. Although the solder pattern is formed with a printing method in the first embodiment and the second embodiment, the solder pattern may be a solder used in a process for connecting a lead and a wiring pattern. In this case, the solder is provided not only between the lead and the wiring pattern but also on the upper face of the lead.

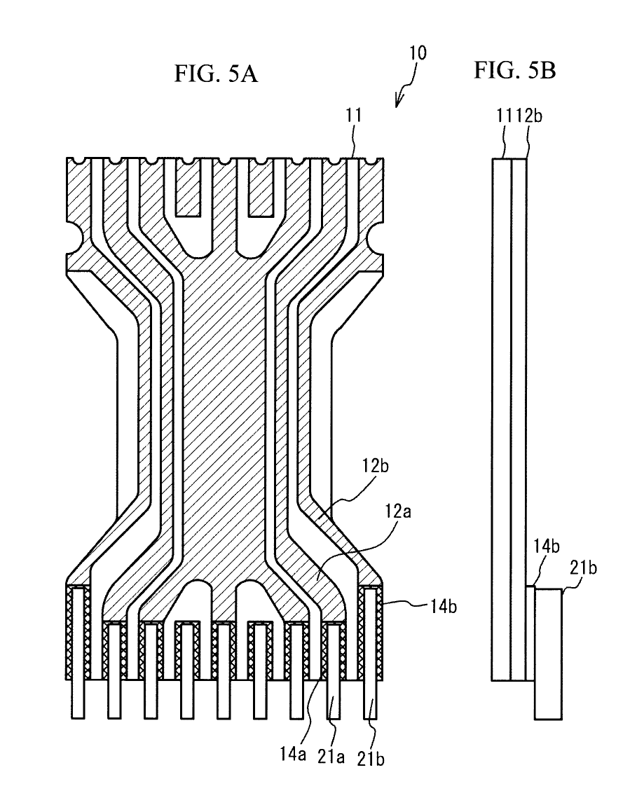

FIG. 5A illustrates a top view of another example of the flexible printed circuit board of the second embodiment. FIG. 5B illustrates a side view of the flexible printed circuit board. As illustrated in FIG. 5A and FIG. 5B, the length of the second lead 21b on the flexible substrate 11 is longer than that of the first lead 21a on the flexible substrate 11. The other structure is the same as that of FIG. 4A and FIG. 4B. The length of the second lead 21b on the flexible substrate 11 is longer than that of the first lead 21a on the flexible substrate 11, in addition to the first solder pattern 14a and the second solder pattern 14b. This allows the stress distribution in the flexible substrate 11, and restrains the breaking of the first wiring pattern 12a and the second wiring pattern 12b more.

### Third Embodiment

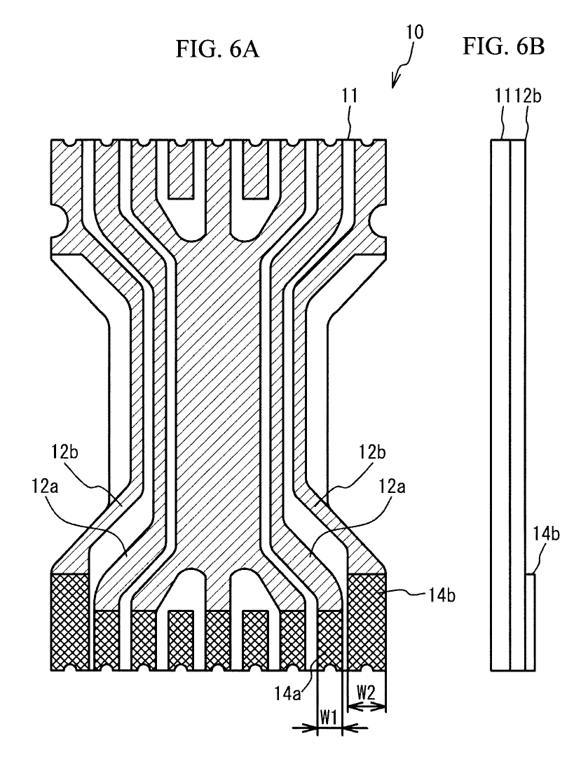

A third embodiment is an example where at least two solder patterns have a different width. FIG. 6A illustrates a top view of a flexible printed circuit board in accordance with the third embodiment. FIG. 6B illustrates a side view of the flexible printed circuit board. As illustrated in FIG. 6A and FIG. 6B, a width W2 of the second solder pattern 14b is larger than a width W1 of the first solder pattern 14a. The width W1 of the first solder pattern 14a is, for example, 0.3 mm. The width W2 of the second solder pattern 14b is, for example, 0.6 mm. The second solder pattern 14b restrains the breaking of the first wiring pattern 12a and the second wiring pattern 12b caused by the stress applied to the flexible substrate 11.

### Fourth Embodiment

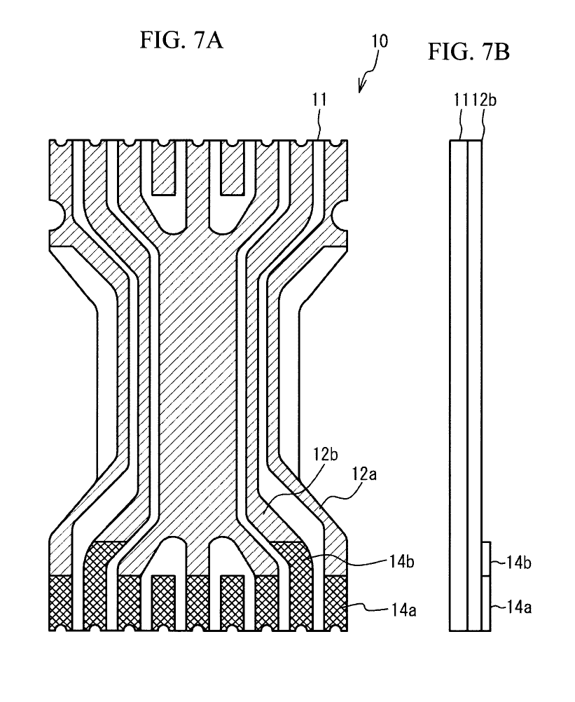

A fourth embodiment is an example where the second solder pattern is located at inner side of the flexible substrate. FIG. 7A illustrates a top view of a flexible printed circuit board in accordance with the fourth embodiment. FIG. 7B illustrates a side view of the flexible printed circuit board. As illustrated in FIG. 7A and FIG. 7B, the second solder pattern 14b having a longer length may be located at inner side (inner side of the array direction of the wiring patterns), the first solder pattern 14a having a shorter length may be located outer side. In this way, the position of the first solder pattern 14a and the second solder pattern 14b may be optional. It is preferable that the solder patterns are arranged symmetrically with respect to a centerline of the flexible substrate 11 extending in the extending direction of the wiring pattern, in view of distribution of the stress.

### Fifth Embodiment

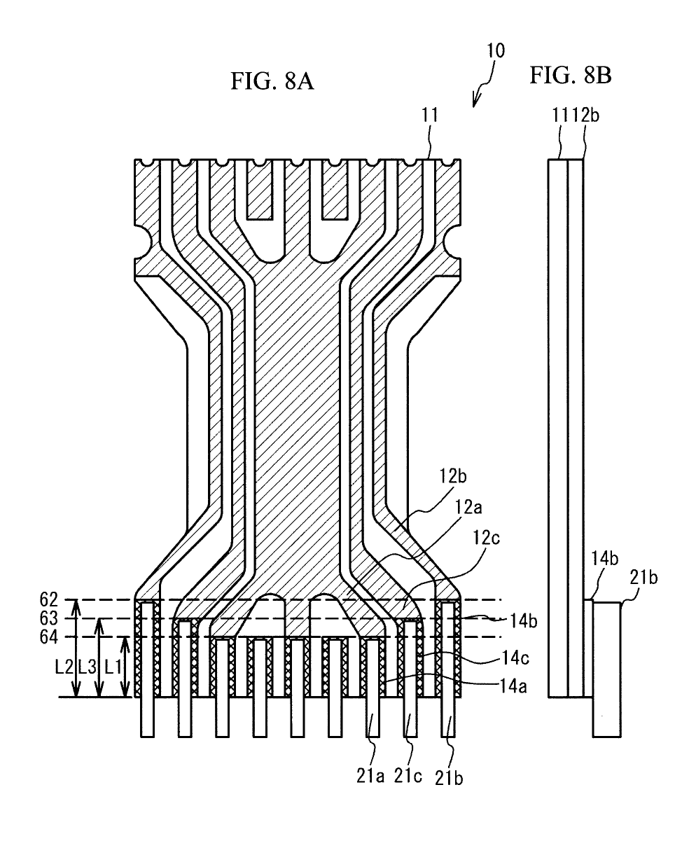

A fifth embodiment is an example where a third solder pattern 14c is disposed. FIG. 8A illustrates a top view of a flexible printed circuit board in accordance with a fifth embodiment. FIG. 8B illustrates a side view of the flexible printed circuit board. As illustrated in FIG. 8A, a third wiring pattern 12c is disposed on the flexible substrate 11. The third solder pattern 14c having a length longer than the first solder pattern 14a and shorter than the second solder pattern 14b is disposed on a lead connection portion of the third wiring pattern 12c on the first side of the flexible substrate 11. The length L1 of the first solder pattern 14a is, for example, 1.0 mm. The length L2 of the second solder pattern 14b is, for example, 2.0 mm. The length L3 of the third solder pattern 14c is, for example, 1.5 mm. The other structure is the same as that of FIG. 2A and FIG. 2B.

In accordance with the fifth embodiment, the stress is distributed into three dotted lines 62 to 64 illustrated in FIG. 8A. Therefore, each stress is more reduced, and the breaking of the first wiring pattern 12a to the third wiring pattern 12c may be restrained more.

The length of a third lead 21c on the flexible substrate 11 is longer than that of the first lead 21a on the flexible substrate 11, and is shorter than that of the second lead 21b on the flexible substrate 11. This may restrain the breaking of the first wiring pattern 12a to the third wiring pattern 12c more.

The third wiring pattern 12c is located between the first wiring pattern 12a and the second wiring pattern 12b. This may distribute the stress applied to the first wiring pattern 12a to the third wiring pattern 12c more.

In the fifth embodiment, the first solder pattern 14a is located outermost of the flexible substrate 11, and the second solder pattern 14b is located around the center of the flexible substrate 11. The third solder pattern 14c is located between the second solder pattern 14b and the first solder pattern 14a. Thus, the solder patterns may be arranged in a fan like shape. The arrangement of the solder patterns is not limited to the example, and may be wave shape. It is preferable that the solder patterns are arranged symmetrically with respect to a centerline of the flexible substrate 11 extending in the extending direction of the wiring pattern, in view of distribution of the stress.

### Sixth Embodiment

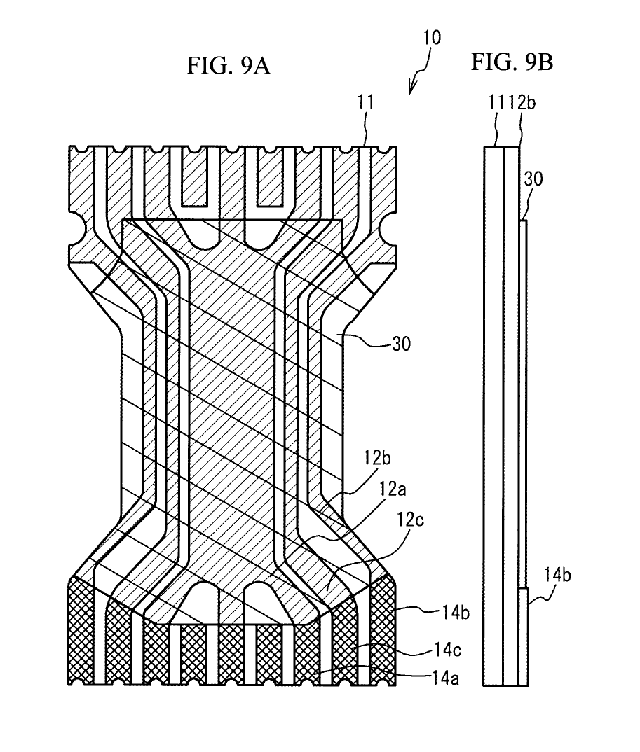

A sixth embodiment is an example where a flexible substrate has a covering sheet. FIG. 9A illustrates a top view of a flexible printed circuit board in accordance with the sixth embodiment. FIG. 9B illustrates a side view of the flexible printed circuit board. As illustrated in FIG. 9A, a covering sheet 30 is provided on the first wiring pattern 12a to the third wiring pattern 12c except for both of the edge portions of the flexible substrate 11. The covering sheet 30 is an insulating layer made of a resin such as polyimid resin. For example, the covering sheet 30 has a thickness of 20 μm. The covering sheet 30 prevents foreign substance being adhered to the first wiring pattern 12a to the third wiring pattern 12c. In addition, the covering sheet 30 restrains the breaking of the first wiring pattern 12a to the third wiring pattern 12c when the flexible substrate 11 is bended. The first solder pattern 14a, the second solder pattern 14b and the third solder pattern 14c extend to the edge of the covering sheet 30. The other structure is the same as that of FIG. 8A and FIG. 8B.

In accordance with the sixth embodiment, the first solder pattern 14a, the second solder pattern 14b and the third solder pattern 14c extend to the edge of the covering sheet 30. In other words, the covering sheet 30 makes the first solder pattern 14a and the second solder pattern 14b expose. And, the first solder pattern 14a and the second solder pattern 14b extend to an interface between the covering sheet 30 and the solder patterns. Thus, the covering sheet 30 restrains the breaking of the first wiring pattern 12a to the third wiring pattern 12c in the area where the covering sheet 30 is provided. The first solder pattern 14a to the third solder pattern 14c restrain the breaking of the first wiring pattern 12a to the third wiring pattern 12c in the area where the first solder pattern 14a to the third solder pattern 14c are disposed. Therefore, the breaking of the first wiring pattern 12a to the third wiring pattern 12c may be restrained more.

### Seventh Embodiment

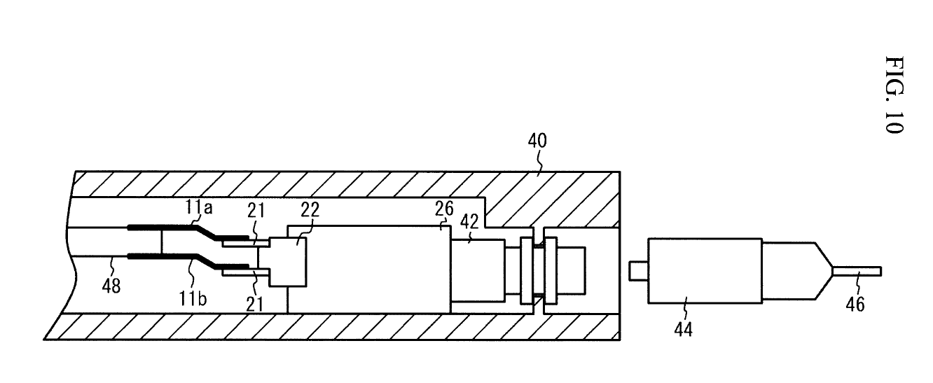

A seventh embodiment is an example where the first embodiment to the sixth embodiment are applied to an optical module. FIG. 10 illustrates a schematic view of the seventh embodiment. FIG. 10 illustrates a cross sectional view of a chassis 40 and a side face of other components. The chassis 40 houses an OSA (Optical Sub Assembly) and a circuit substrate 48. The OSA has a receptacle 42, a package 26, a lead 21 and an insulating body 22. A first edge of a flexible substrate 11a and a first edge of a flexible substrate 11b are coupled to the lead 21. A second edge of the flexible substrate 11a and a second edge of the flexible substrate 11b are coupled to the circuit substrate 48. A connector 44 coupled to an optical fiber 46 is inserted into the receptacle 42. As an example, a light-receiving element such as a photodiode and a preamplifier amplifying an output of the light-receiving element are provided in the package 26. The light-receiving element converts an optical signal coming from the optical fiber 46 into an electrical signal. The preamplifier amplifies the electrical signal. The circuit substrate 48 receives the amplified electrical signal via the insulating body 22, the lead 21 and the flexible substrate lib. The insulating body 22 has a line for transmitting an electrical signal or electrical power. The flexible substrate 11a mainly provides direct current power into the package 26. The flexible substrate 11b transmits a high frequency wave signal between the package 26 and the circuit substrate 48.

The package 26 may house a light-emitting element such as a laser diode and a drive circuit for driving the light-emitting element. In this case, the drive circuit receives an electrical signal from the circuit substrate 48 via the flexible substrate 11, the lead 21 and the insulating body 22, and amplifies the electrical signal. The laser diode converts the amplified electrical signal into an optical signal and outputs the optical signal to the optical fiber 46.

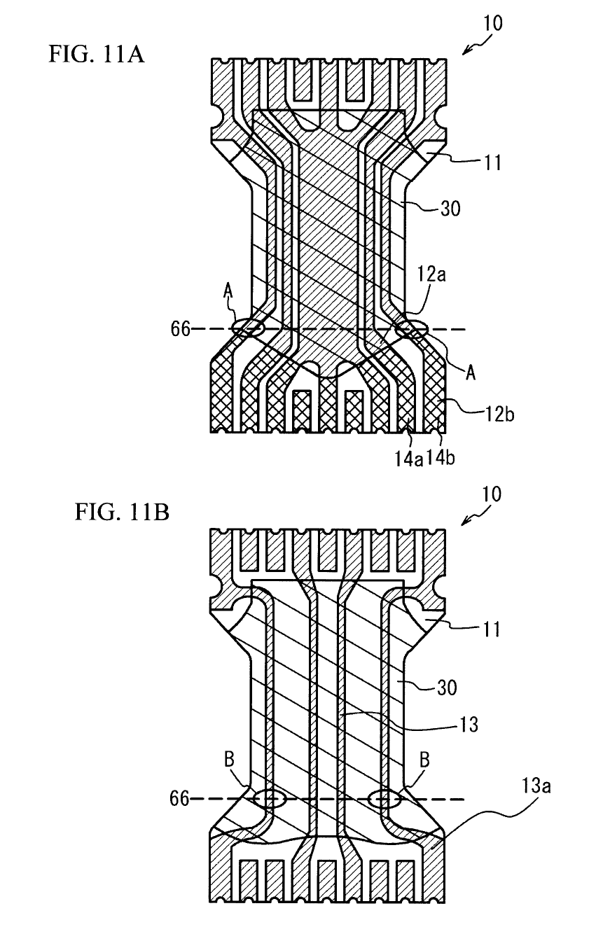

FIG. 11A illustrates an upper face of the flexible substrate of the seventh embodiment. FIG. 11B illustrates a lower face of the flexible substrate. An upper side of FIG. 11A and FIG. 11B is the side of the circuit substrate 48. A lower side of FIG. 11A and FIG. 11B is the side of the insulating body 22. As illustrated in FIG. 11A and FIG. 11B, a wiring pattern 12 is disposed on an upper face of the flexible substrate 11. A wiring pattern 13 is disposed on a lower face of the flexible substrate 11. The covering sheet 30 of the sixth embodiment is provided on the upper face and the lower face of the flexible substrate 11.

As illustrated in FIG. 11A, the second solder pattern 14b on the second wiring pattern 12b of outer side is longer than the first solder pattern 14a on the first wiring pattern 12a of inner side. This restrains stress concentration even if the flexible substrate 11 is bended, and restrains the breaking of the first wiring pattern 12a and the second wiring pattern 12b. In the seventh embodiment, the solder patterns extend to the edge of the covering sheet 30 on all of the wiring patterns, as well as the sixth embodiment.

However, the stress tends to concentrate toward the dotted line 66 of FIG. 11A in the seventh embodiment. Therefore, there may be a case where the second wiring pattern 12b in a circle A is broken. In the seventh embodiment, a number of the first wiring pattern 12a and the second wiring pattern 12b are provided on the upper face side. It is therefore difficult to thicken the second wiring pattern 12b.

On the other hand, as illustrated in FIG. 11B, the wiring pattern 13 is not arranged densely on the lower face of the flexible substrate 11. And so, a wiring pattern 13a is located on a different position from the second wiring pattern 12b on the upper face of the flexible substrate 11. The second wiring pattern 12b on the upper face is coupled to the wiring pattern 13a on the lower face via a contact penetrating the flexible substrate 11 at the edge of the flexible substrate 11. In this case, the wiring pattern 13a on the lower face restrains disconnect of an electrical signal even if the second wiring pattern 12b is broken in the area A. The wiring pattern 13a may be provided on the lower face without the second wiring pattern 12b on the upper face of the flexible substrate 11 from the first edge to the second edge (between the circuit substrate 48 and the insulating body 22).

It is preferable that a wiring pattern crossing a dotted line passing the edge of the second solder pattern 14b where the stress tends to concentrate crosses the dotted line 66 at right angle with the dotted line 66.

It is preferable that in the second to seventh embodiments, the solder is provided on both edges of the wiring pattern 12 of the flexible substrate 11 as well as the first embodiment.

The present invention is not limited to the specifically disclosed embodiments and variations but may include other embodiments and variations without departing from the scope of the present invention.

What is claimed is:

1. A flexible printed circuit board comprising:
a substrate having a first edge and a second edge;
a first wiring pattern disposed on the substrate and having a lead connection portion at a side of the first edge of the substrate;
a second wiring pattern disposed on the substrate and having a lead connection portion at a side of the first edge of the substrate;
a first solder pattern disposed on the lead connection portion of the first wiring pattern; and
a second solder pattern disposed on the lead connection portion of the second wiring pattern and having a length longer than the first solder pattern.

2. The flexible printed circuit board according to claim 1, further comprising:
a third wiring pattern disposed on the substrate and having a lead connection portion at a side of the first edge of the substrate; and
a third solder pattern that is disposed on the lead connection portion of the third wiring pattern and is longer than a length of the first solder pattern and shorter than a length of the second solder pattern.

3. The flexible printed circuit board according to claim 1, further comprising
a covering sheet disposed on the first and second wiring patterns, the first and second solder pattern being exposed from the covering sheet.

4. The flexible printed circuit board according to claim 3, wherein the first and second solder patterns are extended to an edge of the covering sheet.

5. The flexible printed circuit board according to claim 2, wherein the third wiring pattern is arranged between the first and second wiring patterns.

6. The flexible printed circuit board according to claim 1, wherein the second solder pattern has a width larger than a width of the first solder pattern.

7. An optical sub-assembly comprising:
a package for holding an optical device;
leads electrically connected to the optical device; and
a flexible printed circuit board connected to the leads,
the flexible printed circuit board comprising: a substrate having a first edge and a second edge; a first wiring pattern disposed on the substrate and having a lead connection portion at a side of the first edge of the substrate; a second wiring pattern disposed on the substrate and having a lead connection portion at a side of the first edge of the substrate; a first solder pattern disposed on the lead connection portion of the first wiring pattern; and a second solder pattern disposed on the lead connection portion of the second wiring pattern and having a length longer than the first solder pattern.

8. The optical sub-assembly according to claim 7, wherein a length in which the lead and the second solder pattern are contacted is longer than a length in which the lead and the first solder pattern are contacted.

9. The optical sub-assembly according to claim 7, wherein the flexible printed circuit board has a third wiring pattern that is disposed on the substrate and has a lead connection portion at a side of the first edge of the substrate, and a third solder pattern that is disposed on the lead connection portion of the third wiring pattern and is longer than a length of the first solder pattern and shorter than a length of the second solder pattern.

10. The optical sub-assembly according to claim 9, wherein a length in which the lead and the second solder pattern are contacted is longer than a length in which the lead and the third solder pattern are contacted.

11. The optical sub-assembly according to claim 10, wherein a length in which the lead and the third solder pattern are contacted is longer than a length in which the lead and the first solder pattern are contacted.

12. The optical sub-assembly according to claim 7, wherein a length in which the lead and the second solder pattern are contacted is the same as a length in which the lead and the first solder pattern are contacted.
